(19) United States
(12) Patent Application Publication
(10) Pub. No.: US 2009/0008638 A1
(43) Pub. Date: Jan. 8, 2009

(54) Oxide semiconductor, thin film transistor including the same and method of manufacturing a thin film transistor

(75) Inventors: Dong-hun Kang, Yongin-si (KR); I-hun Song, Seongam-si (KR); Young-soo Park, Yongin-si (KR); Chang-jung Kim, Yongin-si (KR); Eun-ha Lee, Seoul (KR); Jae-cheol Lee, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/078,706

(22) Filed: Apr. 3, 2008

(30) Foreign Application Priority Data
Jul. 4, 2007 (KR) 10-2007-0067131

(51) Int. Cl. H01L 29/12; H01L 21/336

(52) U.S. Cl. 257/43; 438/104; 257/E29.068; 257/E21.411

(57) ABSTRACT

Example embodiments relate to an oxide semiconductor including zinc oxide (ZnO), a thin film transistor including a channel formed of the oxide semiconductor and a method of manufacturing the thin film transistor. The oxide semiconductor may include a GaₓIn_{y}Zn_{z} oxide and at least one material selected from the group consisting of a 4A group element, a 4A group oxide, a rare earth element and combinations thereof.

### PRIORITY STATEMENT

This application claims the benefit of priority under 35 USC §119 from Korean Patent Application No. 10-2007-0067131, filed on Jul. 4, 2007 in the Korean Intellectual Property Office (KIPO), the entire contents of which are herein incorporated by reference.

### BACKGROUND

1. Field

Example embodiments relate to an oxide semiconductor and a thin film transistor including the same. Other example embodiments relate to an oxide semiconductor including zinc oxide (ZnO), a thin film transistor including a channel formed of the oxide semiconductor and a method of manufacturing the thin film transistor.

2. Description of the Related Art

A thin film transistor may be used in a variety of fields. Thin film transistors may be used as switching devices and driving devices. Thin film transistors may be used as switches to select a cross-point memory.

An amorphous silicon thin film transistor (a-Si TFT) may be used as a driving device and a switching device for a display. A-Si TFTs are the most commonly used devices for driving and switching devices. It is relatively inexpensive to form a-Si TFTs uniformly on a large-sized substrate having a side length greater than 2 m. As displays become larger and/or definition increases, it is desirable to obtain devices having higher efficiency.

Conventional a-Si TFTs having a mobility of about 0.5 cm²/Vs are limited in use. As such, highly-efficient TFTs having a mobility greater than that of conventional a-Si TFTs and a method of manufacturing the TFTs may be desirable.

Poly-crystalline silicon thin film transistors (p-Si TFT) have a higher efficiency than that of conventional a-Si TFTS. Because p-Si TFTs have a higher mobility of several tens to several hundreds of cm²/Vs, the p-Si TFTs may be used in (or applied to) a high-definition display. A device having a p-Si TFT has decreased deterioration compared to the conventional a-Si TFT. Manufacturing p-Si TFTs involves performing several complicated and expensive processes.

Compared to a-Si TFTs, p-Si TFTs may be more appropriately used in high-definition products, organic light emitting diodes (OLEDs) or the like. Because p-Si TFTs are less cost-effective than conventional a-Si TFTs, the use of p-Si TFTs may be limited.

Because manufacturing a large-sized substrate having a side length greater than 1 m has not been realized yet due to technical problems (e.g., manufacturing equipments limits, poor uniformity, etc.), it is cumbersome to use p-Si TFTs in displays (including televisions and computer monitors) and other display products.

Research involving new TFTs having desirable electrical properties of both conventional a-Si TFTs and p-Si TFTs is being performed. An oxide semiconductor device is representative of such TFT.

Some research has focused on the use of ZnO, IZO (InZnO), GIZO (GaInZnO) and the like in materials for the oxide semiconductor device. Because the oxide semiconductor device may be manufactured using a lower temperature process and is in an amorphous phase, a large-sized oxide semiconductor device may be more easily realized. An oxide semiconductor film includes a material having a higher mobility and higher electrical properties (e.g., a poly-crystalline silicon).

### SUMMARY

Example embodiments relate to an oxide semiconductor and a thin film transistor including the same. Other example embodiments relate to an oxide semiconductor including zinc oxide (ZnO), a thin film transistor including a channel formed of the oxide semiconductor and a method of manufacturing the thin film transistor.

Other example embodiments provide a thin film transistor including a channel formed of the oxide semiconductor that increases electrical properties of the thin film transistor.

According to example embodiments, there is provided an oxide semiconductor including a GaₓIn_{y}Zn_{z} oxide having at least one material selected from the group consisting of a 4A group element, a 4A group oxide, a rare earth element and combinations thereof.

The oxide semiconductor may include a GaₓIn_{y}Zn_{z} oxide compound and at least one material selected from the group consisting of a 4A group element, a 4A group oxide, a rare earth element and combinations thereof.

The 4A group element may be at least one selected from the group consisting of titanium (Ti), zirconium (Zr), hafnium (Hf) and combinations thereof.

The oxide semiconductor may be at least one selected from the group consisting of TiInZn oxide, TiGaInZn oxide and combinations thereof.

An amount of the at least one material may be in a range of 0.01 wt % to 10.00 wt %.

The oxide semiconductor may include a first layer formed of the GaₓIn_{y}Zn_{z} oxide and a material layer formed of at least one material selected from the group consisting of a 4A group element, a 4A group oxide, a rare earth element and combinations thereof. The material layer may have a thickness of 5 nm to 20 nm. The oxide semiconductor may include a second oxide layer formed on the material layer. The second oxide layer may include the GaₓIn_{y}Zn_{z} oxide.

The oxide semiconductor may have a poly-crystalline structure or nano-crystalline structure. The oxide semiconductor may include a poly-crystalline structure or a mixed-phase of a nano-crystalline structure and an amorphous structure.

In the GaₓIn_{y}Zn_{z} oxide, x, y, and z may represent an atomic ratio. In the GaₓIn_{y}Zn_{z} oxide, x, y, and z may integers which satisfy at least one of the following equations x+y+z=1, x+y=1, x+z=1, y+z=1 and z=1.

According to example embodiments, there is provided a thin film transistor, including a gate, a channel corresponding to the gate, a gate insulating layer formed between the gate and the channel, and a source and a drain each contacting a side portion of the channel. The channel may be formed of an oxide semiconductor including a GaₓIn_{y}Zn_{z} oxide having at least one material selected from the group consisting of 4A group element, a 4A group oxide, a rare earth element and combinations thereof.

According to example embodiments, there is provided a method of manufacturing a thin film transistor including forming a gate and a gate insulating layer on the gate, forming a channel on the gate insulating layer corresponding to the gate, and forming a source and a drain each contacting a side portion of the channel. The channel may be formed of a GaₓIn_{y}Zn_{z} oxide having at least one selected from the group consisting of a 4A group element, a 4A group oxide, a rare earth element and combinations thereof.

The channel may be formed by doping the GaₓIn_{y}Zn_{z} oxide using a sputtering method, chemical vapor deposition (CVD), atomic layer deposition (ALD), laser assisted deposition, ion implantation, ion shower or like method.

The channel may be formed by depositing and diffusing at least one material in the GaₓIn_{y}Zn_{z} oxide using a thermal treatment.

The method may include forming of a first oxide layer having the GaₓIn_{y}Zn_{z} oxide, and forming a material layer including the at least one material.

The method may include performing a thermal treatment at a temperature of 100° C. to 450° C. using a furnace, rapid thermal annealing laser, hot plate or the like.

### BRIEF DESCRIPTION OF THE DRAWINGS

Example embodiments will be more clearly understood from the following detailed description taken in conjunction with the accompanying drawings. FIGS. 1-5 represent non-limiting, example embodiments as described herein.

FIG. 1 is a diagram illustrating a cross-sectional view of a thin film transistor including a channel formed of an oxide semiconductor according to example embodiments;

FIGS. 2A through 2E are diagrams illustrating cross-sectional views of a method of manufacturing a thin film transistor according to example embodiments invention;

FIG. 3 is a graph illustrating electrical properties of a thin film transistor according to example embodiments and a conventional thin film transistor in terms of gate voltage (Vg) and drain current (Id);

FIG. 4 is a graph illustrating mobility properties of a thin film transistor according to example embodiments and a conventional thin film transistor; and

FIG. 5 is a graph illustrating results of SIMS analysis obtained after a channel is formed by adding titanium (Ti) in GIZO at a sputtering power of about 30 W to 50 W according to example embodiments.

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments relate to an oxide semiconductor and a thin film transistor including the same. Other example embodiments relate to an oxide semiconductor including zinc oxide (ZnO), a thin film transistor including a channel formed of the oxide semiconductor and a method of manufacturing the thin film transistor.

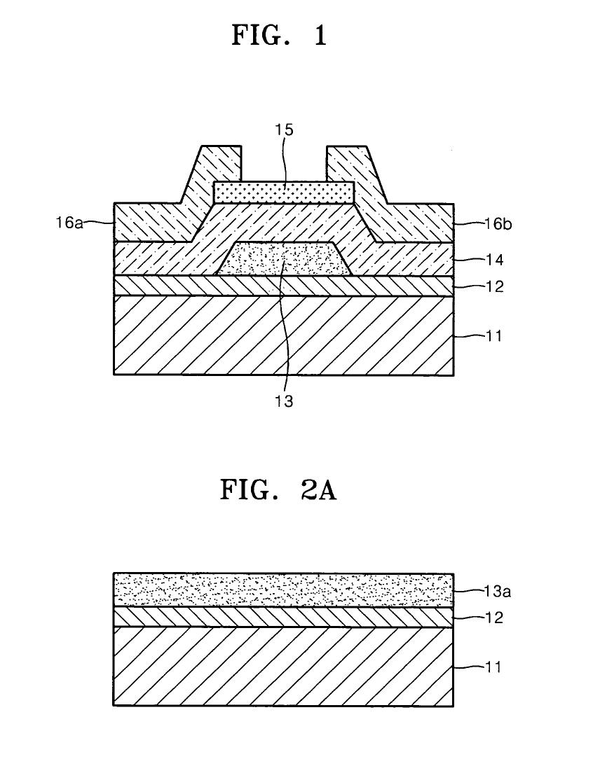

FIG. 1 is a diagram illustrating a cross-sectional view of a thin film transistor including a channel formed of an oxide semiconductor according to example embodiments.

In FIG. 1, the thin film transistor is illustrated as bottom-gate type thin film transistor. However, example embodiments are not limited thereto. The thin film transistor according to example embodiments may be formed as a top-gate type and/or bottom-gate type.

Referring to FIG. 1, the thin film transistor according to example embodiments includes a substrate 11, an insulating layer 12 formed on a top surface of the substrate 11, a gate 13 formed on a top surface of the insulating layer 12, a gate insulating layer 14 formed on the substrate 11 enclosing (or covering) the gate 13, a channel 15 formed on the gate insulating layer 14, and source 16a and drain 16b formed on side surfaces of the channel. The channel 15 may be formed of a GaₓIn_{y}Zn_{z} oxide including at least one material selected from the group consisting of a 4A group element, a 4A group oxide, a rare earth element and combinations thereof.

The substrate 11 may be formed of any well-know material used to form a substrate in a semiconductor device. The substrate 11 may be formed of silicon, glass, plastic, an organic material or the like. If the substrate 11 is formed of silicon, the insulating layer 12 may be formed by depositing a SiO₂ thermal oxidation material on the top surface of the substrate 11 using a thermal oxidation process.

The gate 13 may be formed of a conductive material (e.g., a metal or a metal oxide). The gate insulating layer 14 may be formed of well-known insulating materials used in semiconductor devices. The gate insulating layer 14 may be formed of silicon oxide, nitride or the like. The gate insulating layer 14 may be formed of an insulating material (e.g., HfO₂, Al₂O₃, Si₃N₄ or combinations thereof) or a high-k material having a dielectric constant higher than that of SiO₂, SiO₂ or the like.

The source 16a and the drain 16b may be formed of a conductive material. The conductive material may be a metal (e.g., Cr, Pt, Ru, Au, Ag, Mo, Al, W, Cu, AlNd or the like), a metal oxide (e.g., ITO, GIZO, GZO, AZO, IZO (InZnO), AZO (AlZnO) or the like) or a conductive oxide.

In the thin film transistor according to example embodiments, the channel 15 may be formed of a GaₓIn_{y}Zn_{z} oxide including at least one of material selected from the group consisting of a 4A group element, a 4A group oxide, a rare earth element and combinations thereof. The GaₓIn_{y}Zn_{z} oxide may be at least one selected from the group consisting of GaIn oxide, InZn oxide, GaInZn oxide, Zn oxide and combinations thereof. In the GaₓIn_{y}Zn_{z} oxide, x, y, and z represent an atomic ratio. In the GaₓIn_{y}Zn_{z} oxide, x, y, and z may be integers which satisfy at least one of the following equations: x+y+z=1, x+y=1, x+z=1, y+z=1 and z=1.

The 4A group element may be at least one selected from the group consisting of titanium (Ti), zirconium (Zr), hafnium (Hf) and combinations thereof.

The rare earth element may be at least one selected from the group consisting of Yi, La, Pr, Nd, Dy, Ce, Y, Tb, Gd, Er, Yb and combinations thereof.

The channel 15 may have a structure wherein the at least one material is doped in the oxide semiconductor. The channel 15 may have a structure wherein the GaₓIn_{y}Zn_{z} oxide and the at least one material are mixed together.

According to example embodiments, about 0.01 wt % to about 10.00 wt % of the at least one material may be added to GaₓIn_{y}Zn_{z} oxide (e.g., Zn oxide).

The channel 15 may have a thickness of less than 200 nm. The channel 15 may be formed as a multi-layered structure having a first oxide layer that includes the GaₓIn_{y}Zn_{z} oxide, and a material layer that includes the at least one material. The channel 15 may selectively have a second oxide layer on the material layer. The second oxide layer may include the GaₓIn_{y}Zn_{z} oxide. The first layer and the material layer may be alternately formed. According to example embodiments, the first and the second oxide layer may include the same, or different, GaₓIn_{y}Zn_{z} oxides.

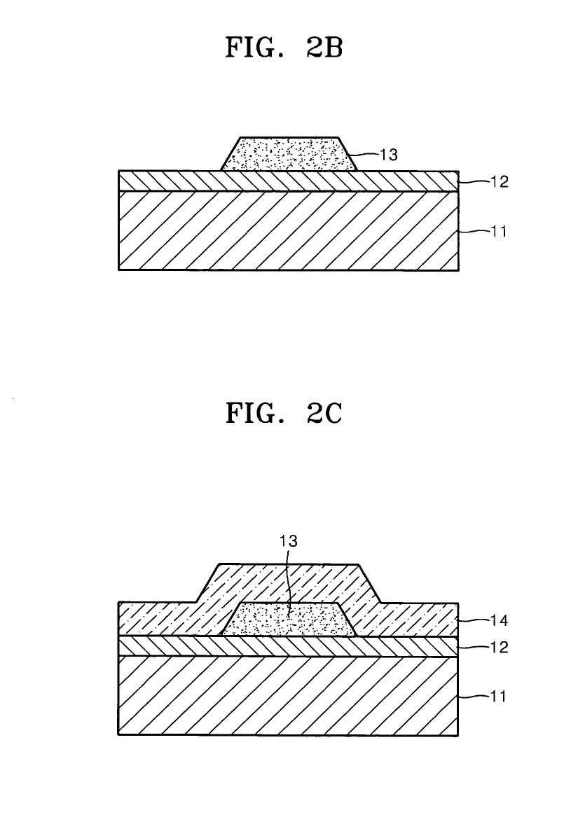

A method of manufacturing a thin film transistor according to example embodiments with reference to FIGS. 2A through 2E will now be described.

FIGS. 2A through 2E are diagrams illustrating cross-sectional views of a method of manufacturing the thin film transistor according to example embodiments;

Referring to FIG. 2A, a substrate 11 is prepared. An insulating layer 12 may be formed on the substrate 11. A conductive material 13a (e.g., a metal or a metal oxide) may be deposited on the substrate 11 and/or the insulating layer 12. The substrate 11 may be formed of silicon, glass, an organic material or the like. If the substrate 11 is formed of silicon, the insulating layer 12 may be formed on the substrate 11 using a thermal oxidation process.

Referring to FIG. 2B, a gate 13 may formed by patterning the conductive material 13a.

Referring to FIG. 2C, a gate insulating layer 14 may be formed on the substrate 11 enclosing (or covering) the gate 13 by depositing and patterning an insulating material (e.g., HfO₂, Al₂O₃, Si₃N₄ or combinations thereof) or a high-k material having a dielectric constant higher than that of SiO₂ or SiO₂ or the like.

Referring to FIG. 2D, a channel 15 may be formed on the gate insulating layer 14 by depositing and patterning a channel material. A portion of the channel material formed in a region corresponding to the gate 13 may remain after patterning.

A process for forming the channel 15 from an oxide semiconductor will now be described.

If the channel 15 is formed by a sputtering process, the GaₓIn_{y}Zn_{z} oxide and the at least one material may deposited on the gate insulating layer 14, after depositing targets for the GaₓIn_{y}Zn_{z} oxide and the at least one material, respectively. If a direct current (DC) sputtering method is used to form the GaₓIn_{y}Zn_{z} oxide, the materials used to form the GaₓIn_{y}Zn_{z} oxide may be simultaneously added. If a radio frequency (RF) sputtering method is used to form the GaₓIn_{y}Zn_{z} oxide, the RF sputtering may be performed on oxide (e.g., TiO₂). The power of the sputtering gun may be adjusted to control an amount of the at least one material included in the GaₓIn_{y}Zn_{z} oxide. A partial pressure of an inert gas and oxygen in a chamber may be adjusted to control an amount of oxygen.

The at least one material may be injected by sputtering, chemical vapor deposition (CVD), atomic layer deposition (ALD), laser assisted deposition, implantation, ion shower doping or the like. The channel 15 may be formed by depositing and diffusing the at least one material in the GaₓIn_{y}Zn_{z} oxide using a thermal treatment (e.g., a thermal annealing or laser annealing). If titanium (Ti) is added to the channel 15, the channel 15 may be formed of at least one selected from the group consisting of TiInZn oxide, TiGaInZn oxide and combinations thereof.

If the channel 15 is formed as a multi-layered structure, the GaₓIn_{y}Zn_{z} oxide and at least one material may be sequentially deposited on the gate insulating layer 14. The GaₓIn_{y}Zn_{z} oxide may be selectively deposited on the gate insulating layer 14.

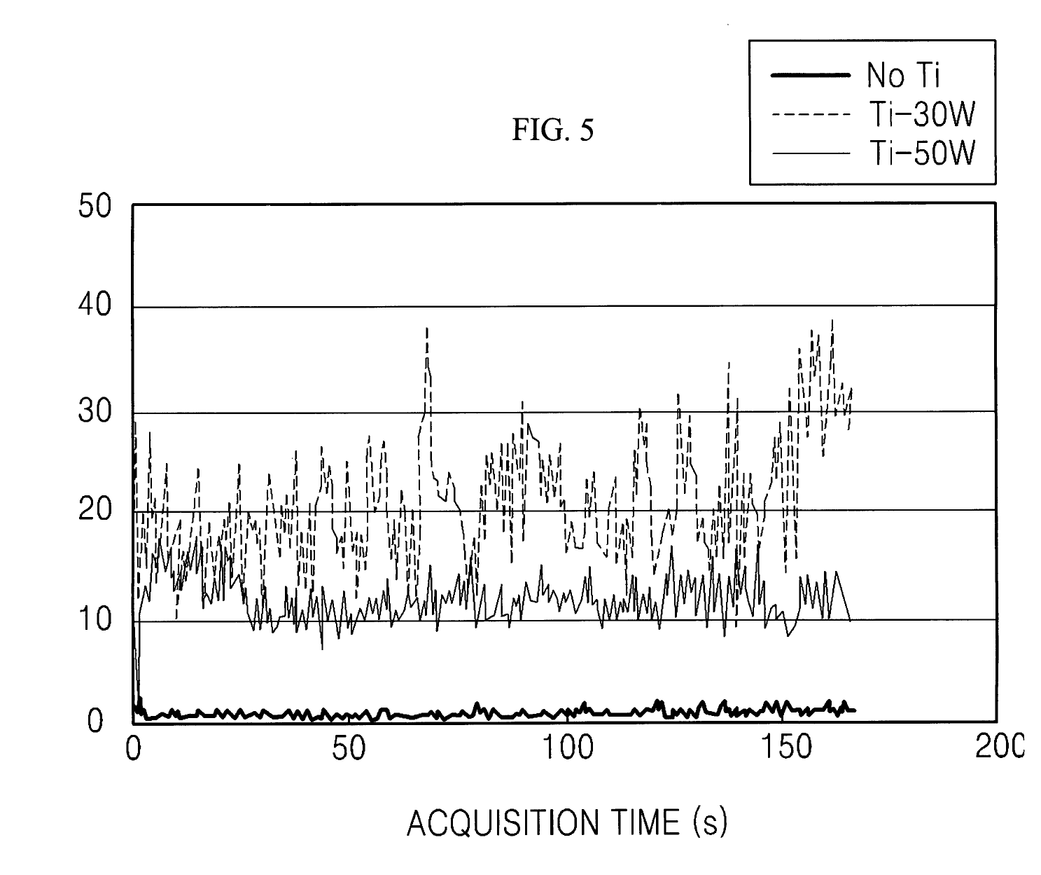

FIG. 5 is a graph illustrating results of SIMS analysis obtained after a channel is formed by adding Ti in GIZO at a sputtering power of about 30 W to 50 W according to example embodiments.

Referring to FIG. 2E, a source 16a and a drain 16b each contacting a side portion of the channel 15 may be formed on the channel 15. The source 16a and drain 16b may be formed by depositing a conductive material (e.g., a metal, a metal oxide or the like) on the channel 15 and the gate insulating layer 14 and patterning an upper portion of the channel 15.

A thermal treatment process may be performed on the channel 15 at a temperature of 100° C. to 450° C. by using a furnace, rapid thermal annealing (RTA), laser, hot plate or the like.

If the channel 15 is formed by doping the at least one material on the GaₓIn_{y}Zn_{z} oxide (e.g., Zn oxide), the channel 15 may include a poly-crystalline structure, nano-crystalline structure or mixed structure thereof.

If the channel 15 has a single-layered structure, a crystalline phase of nanocrystals or microcrystals may be formed in the channel 15. If the channel 15 is has a multi-layered structure, a crystalline phase of polycrystals may be formed in the channel 15.

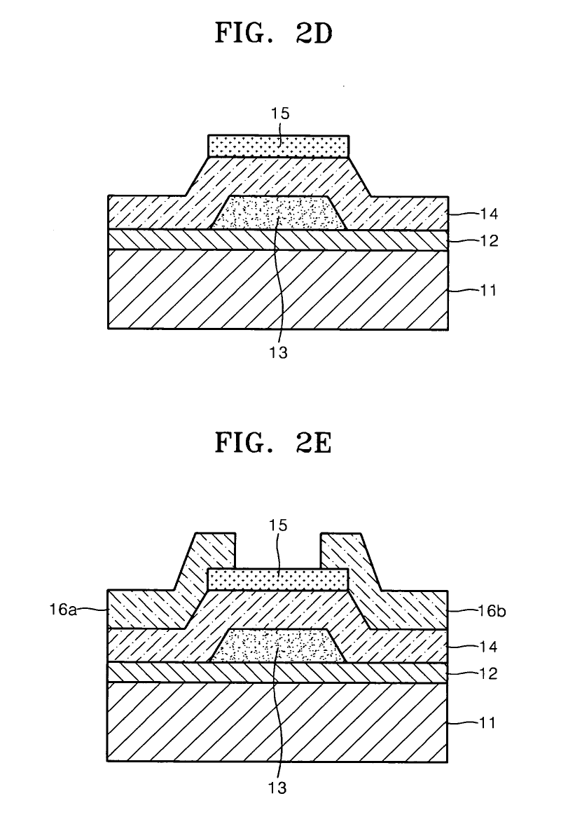

FIG. 3 is a graph illustrating electrical properties of a thin film transistor according to example embodiments and a conventional thin film transistor in terms of gate voltage (Vg) versus drain current (Id).

In FIG. 3, G31 represents a thin film transistor processed by thermal treating at a temperature of 350° C. after forming a channel of GIZO such that a separate material was not added to the GIZO. G32 represents a thin film transistor processed by thermal treating at a temperature of 400° C. after forming a channel of GIZO at a sputtering power of 200 W and titanium (Ti) at a power of 30 W. G33 represents a thin film transistor processed by thermal treating at a temperature of 350° C. after forming a channel of GIZO at a sputtering power of 200 W and titanium (Ti) at a sputtering power of 30 W.

Referring to FIG. 3, the on current was about 10⁻⁵ A and the off current was less than 10⁻¹³ A. As such, the on/off current ratio was more than 10⁸. Each of the thin film transistors in FIG. 3 has increased electrical properties so as to be used as a thin film transistor.

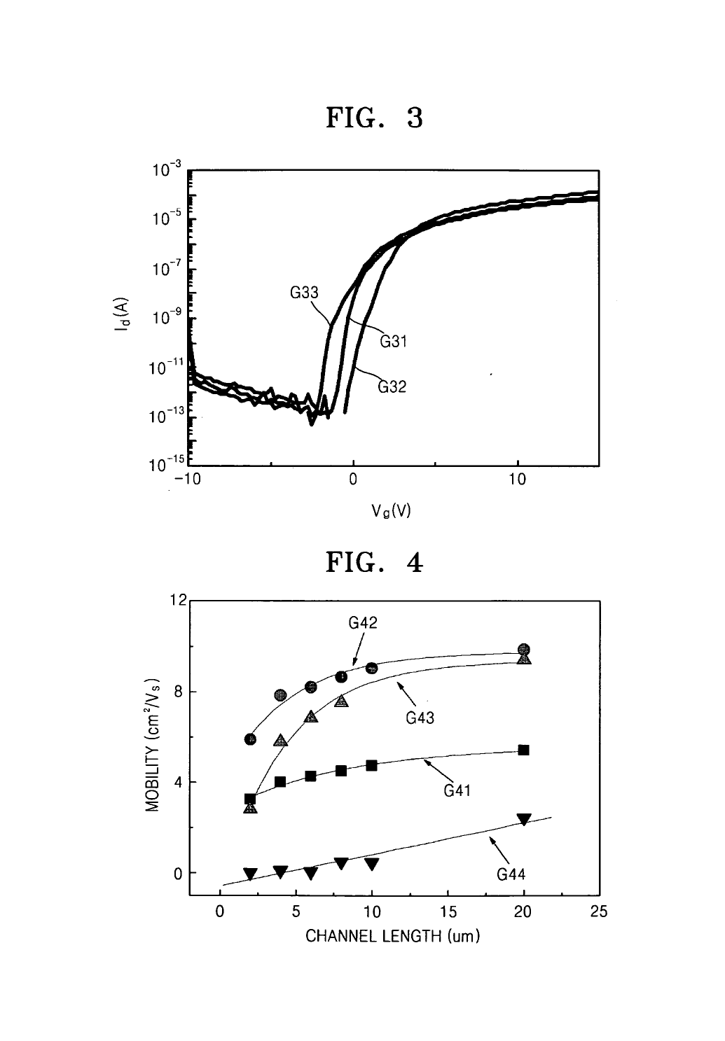

FIG. 4 is a graph illustrating mobility properties of a thin film transistor according to example embodiments and a conventional thin film transistor.

In FIG. 4, G41 represents a thin film transistor processed by thermal treatment at a temperature of 350° C. after forming a channel of GIZO such that a separate material was not added to the GIZO. G42, G43, and G44 are represent thin film transistor processed by thermal treatment at a temperature of 350° C., 400° C. and 450° C., respectively, after forming a channel of GIZO at a sputtering power of 200 W and Ti at a sputtering power of 30 W.

Referring to FIG. 4, the thin film transistor represented by G42 and G43 demonstrate a mobility about two times greater than that of the conventional thin film transistor represented by G41. The thin film transistor represented by G44 has a mobility less than that of the conventional thin film transistor represented by G41. As such, thermal treating the thin film transistor at a temperature of less than 450° C. may increase electrical properties of a device.

According to example embodiments, by forming a channel of a GaₓIn_{y}Zn_{z} oxide having at least one material selected from the group consisting of a 4A group element, a 4A group oxide, a rare earth element and combinations thereof as a single-layer structure or multi-layer structure, the thin film transistor has increased electrical properties (e.g., mobility).

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. In the claims, means-plus-function clauses are intended to cover the structures described herein as performing the recited function, and not only structural equivalents but also equivalent structures. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

1. An oxide semiconductor, comprising:
a GaₓIn_{y}Zn_{z} oxide; and
at least one material selected from the group consisting of a 4A group element, a 4A group oxide, a rare earth element and combinations thereof.

2. The oxide semiconductor of claim 1, wherein the GaₓIn_{y}Zn_{z} oxide is a GaₓIn_{y}Zn_{z} oxide compound.

3. The oxide semiconductor of claim 1, wherein the GaₓIn_{y}Zn_{z} oxide includes the at least one material.

4. The oxide semiconductor of claim 3, wherein an amount of the at least one material is in a range of 0.01 at % to 10.00 at %.

5. The oxide semiconductor of claim 1, wherein the 4A group element is at least one selected from the group consisting of titanium (Ti), zirconium (Zr), hafnium (Hf) and combinations thereof.

6. The oxide semiconductor of claim 5, wherein x, y and z are each independently an integer ranging from 0 to 1, and
the GaₓIn_{y}Zn_{z} oxide is at least one selected from the group consisting of TiInZn oxide, TiGaInZn oxide and combinations thereof.

7. The oxide semiconductor of claim 1, comprising:
a first oxide layer including the GaₓIn_{y}Zn_{z} oxide; and
a material layer on the first oxide layer, wherein the material layer includes the at least one material.

8. The oxide semiconductor of claim 7, wherein the material layer has a thickness of 5 nm to 20 nm.

9. The oxide semiconductor of claim 7, further comprising a second oxide layer on the material layer, wherein the second oxide layer includes the GaₓIn_{y}Zn_{z} oxide.

10. The oxide semiconductor of claim 1, wherein the oxide semiconductor has a poly-crystalline structure or nano-crystalline structure.

11. The oxide semiconductor of claim 1, wherein the oxide semiconductor has a poly-crystalline structure or a mixed-phase of a nano-crystalline structure and an amorphous structure.

12. The oxide semiconductor of claim 1, wherein, x, y, and z represent an atomic ratio, and at least one of the following equations x+y+z=1, x+y=1, x+z=1, y+z=1 and z=1 is satisfied.

13. A thin film transistor, comprising:
a gate;
a channel corresponding to the gate, wherein the channel includes the oxide semiconductor according to claim 1;
a gate insulator between the gate and the channel; and
a source and a drain each contacting a side surface of the channel.

14. The thin film transistor of claim 13, wherein the GaₓIn_{y}Zn_{z} oxide is a GaₓIn_{y}Zn_{z} oxide compound.

15. The thin film transistor of claim 13, wherein the GaₓIn_{y}Zn_{z} oxide includes the at least one material.

16. The thin film transistor of claim 15, wherein an amount of the at least one material is in a range of 0.01 at % to 10.00 at %.

17. The thin film transistor of claim 13, wherein the 4A group element is at least one selected from the group consisting of titanium (Ti), zirconium (Zr), hafnium (Hf) and combinations thereof.

18. The thin film transistor of claim 17, wherein x, y and z are each independently an integer ranging from 0 to 1, and
the GaₓIn_{y}Zn_{z} oxide is at least one selected from the group consisting of TiInZn oxide, TiGaInZn oxide and combinations thereof.

19. The thin film transistor of claim 13, wherein the channel includes:
a first oxide layer including the GaₓIn_{y}Zn_{z} oxide; and
a material layer on the first oxide layer, wherein the material layer includes the at least one material.

20. The thin film transistor of claim 19, wherein the material layer has a thickness of 5 nm to 20 nm.

21. The thin film transistor of claim 19, further comprising a second oxide layer on the material layer, wherein the second oxide layer includes the GaₓIn_{y}Zn_{z} oxide.

22. The thin film transistor of claim 13, wherein the oxide semiconductor has a poly-crystalline structure or nano-crystalline structure.

23. The thin film transistor of claim 13, wherein the oxide semiconductor has a poly-crystalline structure or a mixed-phase of a nano-crystalline structure and an amorphous structure.

24. The thin film transistor of claim 13, wherein, x, y, and z represent an atomic ratio, and at least one of the following equations x+y+z=1, x+y=1, x+z=1, y+z=1 and z=1 is satisfied.

25. A method of manufacturing a thin film transistor, comprising:
forming a gate and a gate insulating layer on the gate;
forming a channel on the gate insulating layer corresponding to the gate, wherein the channel includes a GaₓIn_{y}Zn_{z} oxide and at least one material selected from the group consisting of a 4A group element, a 4A group oxide, a rare earth element and combinations thereof; and
forming a source and a drain each contacting a side portion of the channel.

26. The method of claim 25, wherein the at least one material is formed in the GaₓIn_{y}Zn_{z} oxide.

27. The method of claim 26, wherein the channel is formed by doping the GaₓIn_{y}Zn_{z} oxide using at least one method selected from the group consisting of sputtering, CVD, ALD, laser assisted deposition, ion implantation and ion shower.

28. The method of claim 25, wherein the channel is formed by depositing and diffusing the at least one material in the GaₓIn_{y}Zn_{z} oxide using a thermal treatment.

29. The method of claim 28, wherein the thermal treatment is performed at a temperature of 100° C. to 450° C. using a furnace, rapid thermal annealing laser or hot plate.

30. The method of claim 25, comprising:
forming a first oxide layer including the GaₓIn_{y}Zn_{z} oxide; and
forming a material layer including the at least one material.

31. The method of claim 30, wherein the material layer has a thickness of 5 nm to 20 nm.

32. The method of claim 30, further comprising forming a second oxide layer on the material layer, wherein the second oxide layer includes the GaₓIn_{y}Zn_{z} oxide.

33. The method of claim 25, wherein, x, y and z represent an atomic ratio, and at least one of the following equations x+y+z=1, x+y=1, x+z=1, y+z=1, and z=1 is satisfied.
